(19) United States
(12) Patent Application Publication
(10) Pub. No.: US 2026/0371728 A1
(43) Pub. Date: Nov. 19, 2026

(54) ARRAY SUBSTRATE AND DISPLAY PANEL

(71) Applicant: HKC CORPORATION LIMITED, Shenzhen (CN)

(72) Inventors: JIANYU CUI, Shenzhen (CN); Zeyao LI, Shenzhen (CN); Xianfei ZHU, Shenzhen (CN); Tian LAN, Sehnzhen (CN); Pei XU, Shenzhen (CN)

(21) Appl. No.: 19/662,819

(22) Filed: Apr. 29, 2026

(30) Foreign Application Priority Data
May 16, 2025 (CN) 202510633847.1

(51) Int. Cl. H10D 86/40; G02F 1/1362; G02F 1/1368; G02F 1/167; G02F 1/16757; G02F 1/1677

(52) U.S. Cl. CPC H10D 86/421; G02F 1/136286; G02F 1/13685; G02F 1/167; G02F 1/16757; G02F 1/1677; H10D 86/441

(57) ABSTRACT

Disclosed are anarray substrate and a display panel. A first semiconductor structure is disposed between the first source electrode and the first connecting electrode. A second semiconductor structure is disposed between the first connecting electrode and the first drain electrode. The first source electrode, the first semiconductor structure, the first connecting electrode, the second semiconductor structure, and the first drain electrode are connected in series. The pixel electrodes are connected to the first drain electrode. A channel formed between the first source electrode and the first connecting electrode is defined as the first source channel. A channel formed between the first drain electrode and the first connecting electrode is defined as the first drain channel. The length direction of the first source channel and the length direction of the first drain channel form an angle.

### CROSS REFERENCE TO RELATED APPLICATIONS

The present disclosure claims the priority and benefit of Chinese Patent Application No. 202510633847.1, titled “ARRAY SUBSTRATE AND DISPLAY PANEL” and filed on May 16, 2025 with China National Intellectual Property Administration, the entire contents of which are incorporated herein by reference.

### TECHNICAL FIELD

The present disclosure relates to the technical field of display, and particularly to anarray substrate and a display panel.

### BACKGROUND

Electrophoretic display (EPD) technologyhas advantages of low power consumption, power-free display, an ultra-wide viewing angle, and no blue light emission, thus avoiding light pollution. EPD-based products have become popular worldwidebecause of these prominent advantages of the EPD technology. In recent years, foldable EPD panels have gradually entered public view due to the flexible and foldable advantages.

However, during the use of the foldable EPD panels, a grayscale degradation issue may occur when displaying images at the folding region, resulting in uneven image display on the display panel.

### SUMMARY

An objective of the present disclosure is to provide an array substrateand a display panel to avoid the problem of grayscale degradation when displaying images at the folding region and prevent uneven image display on the display panel.

The present disclosure discloses an array substrate including a substrate, a first active switch, and pixel electrodes. The first active switch includes a first gate electrode, a first source electrode, a first connecting electrode, and a first drain electrode. The first gate electrode, the first source electrode, the first connecting electrode, the first drain electrode, and the pixel electrodes are disposed on the substrate. A first semiconductor structure is disposed between the first source electrode and the first connecting electrode. A second semiconductor structure is disposed between the first connecting electrode and the first drain electrode. The first source electrode, the first semiconductor structure, the first connecting electrode, the second semiconductor structure, and the first drain electrode are connected in series. The pixel electrodes are connected to the first drain electrode.

A channel formed between the first source electrode and the first connecting electrode is defined as a first source channel. A channel formed between the first drain electrode and the first connecting electrode is defined as a first drain channel. The length direction of the first source channel and the length direction of the first drain channel form an angle.

Optionally, the length direction of the first source channel is perpendicular to the length direction of the first drain channel.

Optionally, the first connecting electrode includes a first connecting electrode portion and a second connecting electrode portion, and the first connecting electrode portion is vertically connected to the second connecting electrode portion.

The first semiconductor structure is connected to the first source electrode and the first connecting electrode portion, and the second semiconductor structure is connected to the first drain electrode and the second connecting electrode portion.

The first source electrode is arranged in parallel with the first connecting electrode portion, and the first drain electrode is arranged in parallel with the second connecting electrode portion.

Optionally, the array substrate includes a second active switch including a second gate electrode, a second source electrode, a second connecting electrode, and a second drain electrode. The second gate electrode, the second source electrode, the second connecting electrode, and the second drain electrode are disposed on the substrate. The pixel electrodes are further connected to the second drain electrode.

A third semiconductor structure is disposed between the second source electrode and the second connecting electrode. A fourth semiconductor structure is disposed between the second connecting electrode and the second drain electrode. The second source electrode, the third semiconductor structure, the second connecting electrode, the fourth semiconductor structure, and the second drain electrode are connected in series.

A channel formed between the second source electrode and the second connecting electrode is defined as a second source channel. A channel formed between the second drain electrode and the second connecting electrode is defined as a second drain channel. The length direction of the second source channel is perpendicular to the length direction of the second drain channel.

The second connecting electrode includes a third connecting electrode portion and a fourth connecting electrode portion, and the third connecting electrode portion is vertically connected to the fourth connecting electrode portion.

The third semiconductor structure is connected to the second source electrode and the third connecting electrode portion, and the fourth semiconductor structure is connected to the second drain electrode and the fourth connecting electrode portion.

The second source electrode is arranged in parallel with the third connecting electrode portion, and the second drain electrode is arranged in parallel with the fourth connecting electrode portion.

Optionally, the first gate electrode and the second gate electrode are disposed on the same layer. The first source electrode, the first connecting electrode, the first drain electrode, the second source electrode, the second connecting electrode, and the second drain electrode are disposed on the same layer;

The first connecting electrode portion is arranged in parallel with the fourth connecting electrode portion, the first connecting electrode portion is perpendicular to the third connecting electrode portion, the second connecting electrode portion is arranged in parallel with the third connecting electrode portion, and the second connecting electrode portion is perpendicular to the fourth connecting electrode portion.

The first source electrode and the first drain electrode are respectively disposed on two sides of the first connecting electrode portion, and the second source electrode and the second drain electrode are respectively disposed on two sides of the fourth connecting electrode portion, or the first source electrode and the first drain electrode are respectively disposed on two sides of the second connecting electrode portion, and the second source electrode and the second drain electrode are respectively disposed on two sides of the third connecting electrode portion.

Optionally, the first connecting electrode includes a first connecting electrode portion and a second connecting electrode portion, and the first connecting electrode portion is vertically connected to the second connecting electrode portion.

The first source electrode includes a first source portion, a second source portion, and a third source portion, where the first source portion, the second source portion, and the third source portion are connected in series, and the first source portion and the third source portion are disposed on the two sides of the first connecting electrode portion.

The first drain electrode includes a first drain portion, a second drain portion, and a third drain portion, where the first drain portion, the second drain portion, and the third drain portion are connected in series, and the first drain portion and the third drain portion aredisposed on the two sides of the second connecting electrode portion.

Optionally, the array substrate includes the second active switch including the second gate electrode, the second source electrode, the second connecting electrode, and the second drain electrode, where the second gate electrode, the second source electrode, the second connecting electrode, and the second drain electrode are disposed on the substrate, and the pixel electrodes are further connected to the second drain electrode.

The third semiconductor structure is disposed between the second source electrode and the second connecting electrode. The fourth semiconductor structure is disposed between the second connecting electrode and the second drain electrode. The second source electrode, the third semiconductor structure, the second connecting electrode, the fourth semiconductor structure, and the second drain electrode are connected in series.

The channel formed between the second source electrode and the second connecting electrode is defined as the second source channel. The channel formed between the second drain electrode and the second connecting electrode is defined as the second drain channel. The length direction of the second source channel is perpendicular to the length direction of the second drain channel.

The second connecting electrode includes the third connecting electrode portion and the fourth connecting electrode portion, and the third connecting electrode portion is vertically connected to the fourth connecting electrode portion.

The second source electrode includes a fourth source portion, a fifth source portion, and a sixth source portion, where the fourth source portion, the fifth source portion, and the sixth source portion are connected in series, and the fourth source portion and the sixth source portion are disposed on the two sides of the third connecting electrode portion.

The second drain electrode includes a fourth drain portion, a fifth drain portion, and a sixth drain portion, where the fourth drain portion, the fifth drain portion, and the sixth drain portion are connected in series, and the fourth drain portion and the sixth drain portion are disposed on the two sides of the fourth connecting electrode portion.

Optionally, the first gate electrode and the second gate electrode are disposed on the same layer. The first source electrode, the first connecting electrode, the first drain electrode, the second source electrode, the second connecting electrode, and the second drain electrode are disposed on the same layer.

The first connecting electrode portion is arranged in parallel with the fourth connecting electrode portion. The first connecting electrode portion is perpendicular to the third connecting electrode portion. The second connecting electrode portion is arranged in parallel with the third connecting electrode portion. The second connecting electrode portion is perpendicular to the fourth connecting electrode portion.

Optionally, the array substrate further includes data lines and scan lines, both of which are disposed on the substrate. The data linesare connected to the first source electrode of the first active switch, and the scan lines are connected to the first gate electrode of the first active switch.

The present disclosure further discloses a display panel including a driving circuit and the array substrate, and the driving circuit is connected to the array substrate to drive the array substrate.

Compared with the existing array substrate, the present disclosure configures the length direction of the first source channel and the length direction of the first drain channel to form the angle,so that the width of the first drain channel increaseswhen the length of the first source channel increases, the width of the first drain channel decreaseswhen the length of the first source channel decreases, the length of the first drain channel increaseswhen the width of the first source channel increases, and the length of the first drain channel decreaseswhen the width of the first source channel decreases, thereby achieving mutual compensation for changes, avoiding the problem of grayscale degradation when displaying images at the folding region and preventing uneven image display on the display panel.

### BRIEF DESCRIPTION OF THE DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of a display panel according to an embodiment of the present disclosure.

FIG. 2 is a cross-sectional schematic diagram of a display panel according to an embodiment of the present disclosure.

FIG. 3 is a schematic diagram of an array substrate according to the first embodiment of the present disclosure.

FIG. 4 is a schematic diagram of an array substrateincluding a second active switch according to the first embodiment of the present disclosure.

FIG. 5 is a partially enlarged schematic diagram of the active switch in FIG. 4.

FIG. 6 is a schematic diagram of a first gate electrode and a second gate electrode according to the first embodiment of the present disclosure.

FIG. 7 is a schematic plan diagram of an array substrate in a laterally folded stateaccording to the first embodiment of the present disclosure.

FIG. 8 is a schematic diagram of an active switch located at a first folding region according to the first embodiment of the present disclosure.

FIG. 9 is a schematic diagram of an active switch located at a second folding region according to the first embodiment of the present disclosure.

FIG. 10 is a schematic plan diagram of an array substrate in a laterally folded state according to the first embodiment of the present disclosure.

FIG. 11 is a schematic diagram of an active switch located at the first folding region according to the first embodiment of the present disclosure.

FIG. 12 is a schematic diagram of an active switch located at the second folding region according to the first embodiment of the present disclosure.

FIG. 13 is a schematic plan diagram of an array substrate according to the second embodiment of the present disclosure.

FIG. 14 is a schematicplan diagram of an array substrate including dual active switches according to the second embodiment of the present disclosure.

FIG. 15 is a partially enlarged schematic diagram of the active switch in FIG. 14.

Reference Numerals: 10. display panel; 20. driving circuit; 30. array substrate; 40. folding region; 41. first folding region; 42. second folding region; 43. folding line; 51. first direction; 52. second direction; 100. substrate; 200. first active switch; 210. first gate electrode; 220. first source electrode; 221. first source portion; 222. second source portion; 223. third source portion; 240. first connecting electrode; 241. first connecting electrode portion; 242. second connecting electrode portion; 250. first drain electrode; 251. first drain portion; 252. second drain portion; 253. third drain portion; 261. first semiconductor structure; 262. second semiconductor structure; 271. first source channel; 272. first drain channel; 300. second active switch; 310. second gate electrode; 320. second source electrode; 324. fourth source portion; 325. fifth source portion; 326. sixth source portion; 340. second connecting electrode; 343. third connecting electrode portion; 344. fourth connecting electrode portion; 350. second drain electrode; 354. fourth drain portion; 355. fifth drain portion; 356. sixth drain portion; 363. third semiconductor structure; 364. fourth semiconductor structure; 371. second source channel; 372. second drain channel; 400. pixel electrode; 510. data line; 520. scan line; 610. first metal layer; 620. first insulating layer; 630. second metal layer; 640. second insulating layer; 650. passivation layer; 660. pixel electrode layer; 670. reflective film layer; 671. microcapsules; 672. electrophoretic particles; 680. common electrode layer; 710. common electrode; 810. X-axis; 820. Y-axis.

### DETAILED DESCRIPTION

It should be understood that the terminology, specific structures, and functional details disclosed herein are merely configured to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. The term "include" and any variations thereof indicate non-exclusive inclusion, such that there may exist or be added one or more other features, integers, steps, operations, elements, components, and/or combinations thereof.

Additionally, directional or positional terms such as "center," "transversal," "upper," "lower," "left," "right," "vertical," "horizontal," "top," "bottom," "inside," or "outside" are described based on orientations or relative positional relationships shown in the accompanying drawings, which are used for simplified description to facilitate understanding of the present disclosure and do not imply that the devices or elements described should have specific orientations or be constructed or operated in specific orientations. These terms should not be construed as limiting the present disclosure.

Additionally, unless otherwise explicitly specified and limited, the term "mount," "link," "connect," and the like should be understood in a broad sense, for example, as a fixed connection, as a detachable connection, as an integral connection, as a mechanical connection, as an electrical connection, as a direct connection, as an indirect connection through an intermediate medium, or as a connection within two elements. For those skilled in the art, the specific meaning of the above terms in the context of the present disclosure may be understood according to the specific situation.

The present disclosure is described in below in detail with reference to the accompanying drawings and optional embodiments.

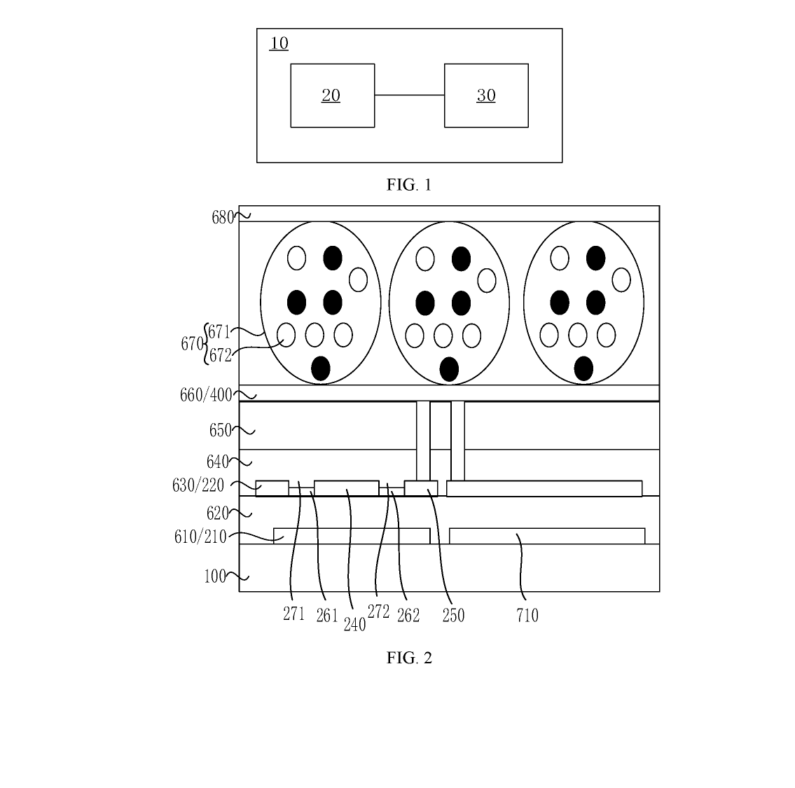

FIG. 1 is a schematic diagram of a display panel according to an embodiment of the present disclosure, and FIG. 2 is a cross-sectional schematic diagram of the display panel according to an embodiment of the present disclosure. As shown in FIGS. 1-2, the present disclosure discloses the display panel 10 including a driving circuit 20 and an array substrate 30, and the driving circuit 20 is connected to the array substrate 30 to drive the array substrate 30.

The technical solution of the present disclosuremay be widely applied to various display panels 10, such as TN (Twisted Nematic) display panels, IPS (In-Plane Switching) display panels, VA (Vertical Alignment) display panels, MVA (Multi-Domain Vertical Alignment) display panels, and of course, it may also be applied to other types of display panels, such as OLED (Organic Light-Emitting Diode) display panels and electronic paper display panels.

Exemplarily, taking the electronic paper display panel 10 as an example, the array substrate 30 includes a substrate 100, a first metal layer 610, a first insulating layer 620, a second metal layer 630, a second insulating layer 640, a passivation layer 650, and a pixel electrode layer 660. The display panel 10 further includes a reflective film layer 670 and a common electrode layer 680. The first metal layer 610, the first insulating layer 620, the second metal layer 630, the second insulating layer 640, the passivation layer 650, and the pixel electrode layer 660 are disposedin series on the substrate 100. The reflective film layer 670 is disposed between the pixel electrode layer 660 and the common electrode layer 680.

The reflective film layer 670 includes microcapsules 671, and the microcapsules 671 are filled with electrophoretic particles 672. An electric field is formed between the pixel electrode layer 660 and the common electrode layer 680 to drive the electrophoretic particles 672 to move up and down, reflecting or absorbing light toachieve image display.

The array substrate 30 further includes a common electrode 710, and the common electrode 710 is disposed within the first metal layer 610 or the second metal layer 630. A storage capacitor is formed between the common electrode 710 and the pixel electrode layer 660.

The present disclosure also discloses the array substrate 30, and he array substrate 30 may be applied to the display panel 10 described above. For the array substrate 30, the present disclosure provides the following designs, which are specifically introduced through several embodiments:

### Embodiment 1

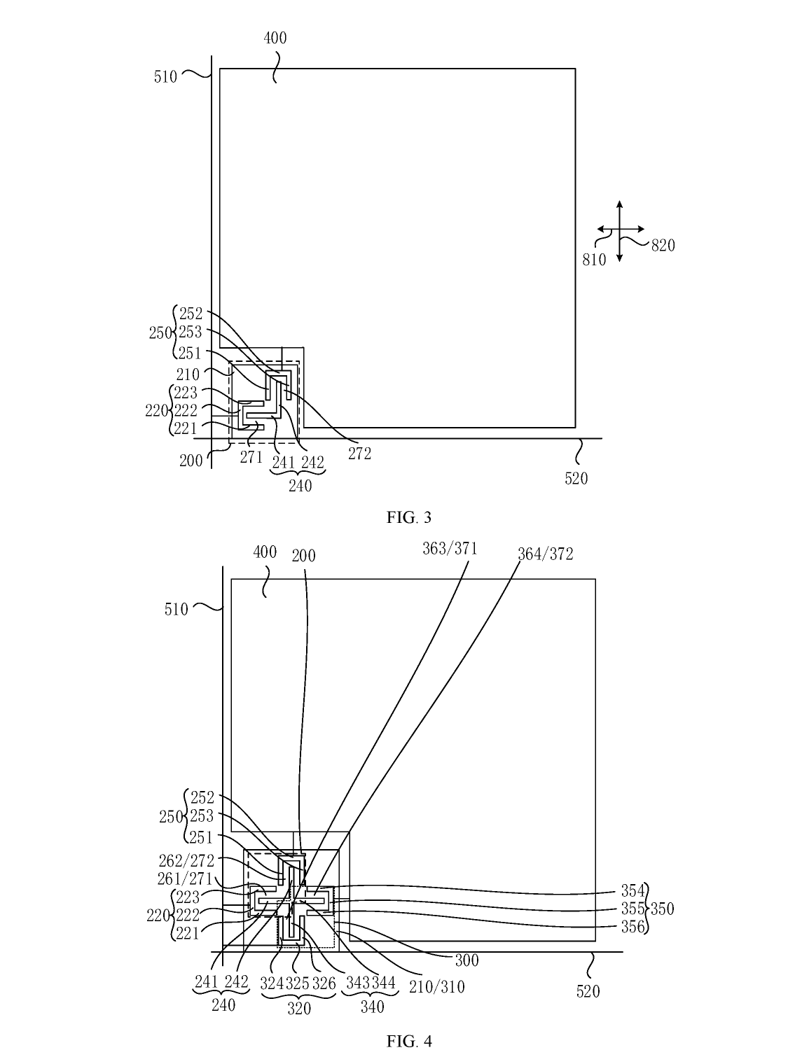

FIG. 3 is a schematic diagram of an array substrate according to the first embodiment of the present disclosure. As shown in FIG. 3, the present disclosure discloses the array substrate 30 including a substrate 100, a first active switch 200, and pixel electrodes 400. The first active switch 200 includes a first gate electrode 210, a first source electrode 220, a first connecting electrode 240, and a first drain electrode 250. The first gate electrode 210, the first source electrode 220, the first connecting electrode 240, the first drain electrode 250, and the pixel electrode 400 are disposed on the substrate 100.

A first semiconductor structure 261 is disposed between the first source electrode 220 and the first connecting electrode 240. A second semiconductor structure 262 is disposed between the first connecting electrode 240 and the first drain electrode 250. The first source electrode 220, the first semiconductor structure 261, the first connecting electrode 240, the second semiconductor structure 262, and the first drain electrode 250 are connected in series.And the pixel electrodes 400 are connected to the first drain electrode 250.

A channel formed between the first source electrode 220 and the first connecting electrode 240 is defined as a first source channel 271, and a channel formed between the first drain electrode 250 and the first connecting electrode 240 is defined as a first drain channel 272. The length direction of the first source channel 271 and the length direction of the first drain channel 272 form an angle. In other words, the length direction of the first source channel 271 is not parallel to the length direction of the first drain channel 272.

The array substrate 30 further includes data lines 510 and scan lines 520, and the data lines 510 and the scan lines 520 are disposed on the substrate 100. The data lines 510 aresimultaneouslyconnected to the first source electrode 220 of the first active switch 200, and the scan lines 520 are connected to the first gate electrode 210 of the first active switch 200. The pixel electrodes 400 are disposed within the pixel electrode layer 660.

Exemplarily, the data lines 510 are disposed within the first metal layer 610, and the scan lines 520 are disposed within the second metal layer 630.

Exemplarily, the data lines 510 are disposed within the second metal layer 630, and the scan lines 520 are disposed within the first metal layer 610.

Exemplarily, the first active switch 200 is a bottom-gate active switch.The first gate electrode 210 is disposed within the first metal layer 610. The first source electrode 220, the first connecting electrode 240, and the first drain electrode 250 are disposed within the second metal layer 630. The first semiconductor structure 261 and the second semiconductor structure 262 are disposed between the first insulating layer 620 and the second metal layer 630.

Exemplarily, the first active switch 200 is a top-gate active switch. The first gate electrode 210 is disposed within the second metal layer 630. The first source electrode 220, the first connecting electrode 240, and the first drain electrode 250 are disposed within the first metal layer 610. The first semiconductor structure 261 and the second semiconductor structure 262 are disposed between the substrate 100 and the first metal layer 610.

The length or width of the channel of the active switch on the existing array substrate 30 will change when the display panel 10 is bent.

The charging capability of the active switch decreases when the length of the channel the active switch increases. As a result, the electrophoretic particles 672 above the pixel electrode 400 connected to the active switch cannot move to a target position, leading to grayscale degradation in this region during display. The leakage currentof the active switch increases when the length of the channel of the active switch decreases. Similarly, the electrophoretic particles 672 above the pixel electrode 400 connected to the active switch still cannot move to the target position, resulting in the grayscale degradation in this region during display.

The charging capability of the active switch declines when the width of the channel channel of the active switch decreases. Consequently, the electrophoretic particles 672 above the pixel electrode 400 connected to the active switch cannot move to the target position, resulting in the grayscale degradation in this region during display. The leakage currentof the active switch rises when the width of the channel of the active switch increases. Similarly, the electrophoretic particles 672 above the pixel electrode 400 connected to the active switch still fail to move to the target position, leading to the grayscale degradation in this region during display.Consequently, it causes the grayscale of the display panel 10 in the folding region 40 to decrease when displaying an image, leading to the problem of the uneven image display onno the entire display panel 10.

Compared with the existing array substrate, the present disclosure configures the length direction of the first source channel 271 and the length direction of the first drain channel 272 to form an angle. Thus, the width of the first drain channel 272 increaseswhen the length of the first source channel 271 increases, the width of the first drain channel 272 decreaseswhen the length of the first source channel 271 decreases, the length of the first drain channel 272 increaseswhen the width of the first source channel 271 increases, and the length of the first drain channel 272 decreaseswhen the width of the first source channel 271 decreases, thereby achieving mutual compensation for changes, avoiding the problem of grayscale degradation when displaying images at the folding region 40 and preventing the uneven image display on the display panel 10.

The display panel 10 can be folded along X-axis 810 direction or Y-axis 820 direction. The length direction of the X-axis 810 is consistent with the width direction of the first source channel 271 and the length direction of the first drain channel 272. The length direction of the Y-axis 820 is consistent with the length direction of the first source channel 271 and the width direction of the first drain channel 272.

Exemplarily, the length direction of the first source channel 271 is perpendicular to the length direction of the first drain channel 272, so that when the display panel 10 is folded along the X-axis 810 direction, the length of the first source channel 271 and the width of the first drain channel 272 increase or decrease synchronously, while the width of the first source channel 271 and the length of the first drain channel 272 remain unchanged.

When the display panel 10 is folded along the Y-axis 820 direction, the width of the first source channel 271 and the length of the first drain channel 272 increase or decrease synchronously, while the length of the first source channel 271 and the width of the first drain channel 272 remain unchanged, thereby leading to a better effect of mutual offset between the variation of the first source channel 271 and the variation of the first drain channel 272.

Referring to FIG. 3, the first source electrode 220 and the first drain electrode 250 disclosed in this embodiment are U-shaped, specifically as follows: the first connecting electrode 240 includes a first connecting electrode portion 241 and a second connecting electrode portion 242, and the first connecting electrode portion 241 is vertically connected to the second connecting electrode portion 242.

The first source electrode 220 includes a first source portion 221, a second source portion 222, and a third source portion 223. The first source portion 221, the second source portion 222, and the third source portion 223 are connected in series. The first source portion 221 and the third source portion 223 are disposed on two sides of the first connecting electrode portion 241.

The first drain electrode 250 includes a first drain portion 251, a second drain portion 252, and a third drain portion 253. The first drain portion 251, the second drain portion 252, and the third drain portion 253 are connected in series. The first drain portion 251 and the third drain portion 253 are disposed on two sides of the second connecting electrode portion 242.

The first active switch 200 is a dual-gate active switch, which occupies a relatively large area of a single pixel unit region. It should be understood that pixel unit region is defined by the crisscrossing arrangement of the data lines 510 and the scan lines 520. The area of the first active switch 200 may be reduced by configuring the first source electrode 220 and the first drain electrode 250 into a U-shape, thereby allowing the common electrode 710 to have more space, enabling the common electrode 710 to be designed sufficiently large to increase the size of the storage capacitor.

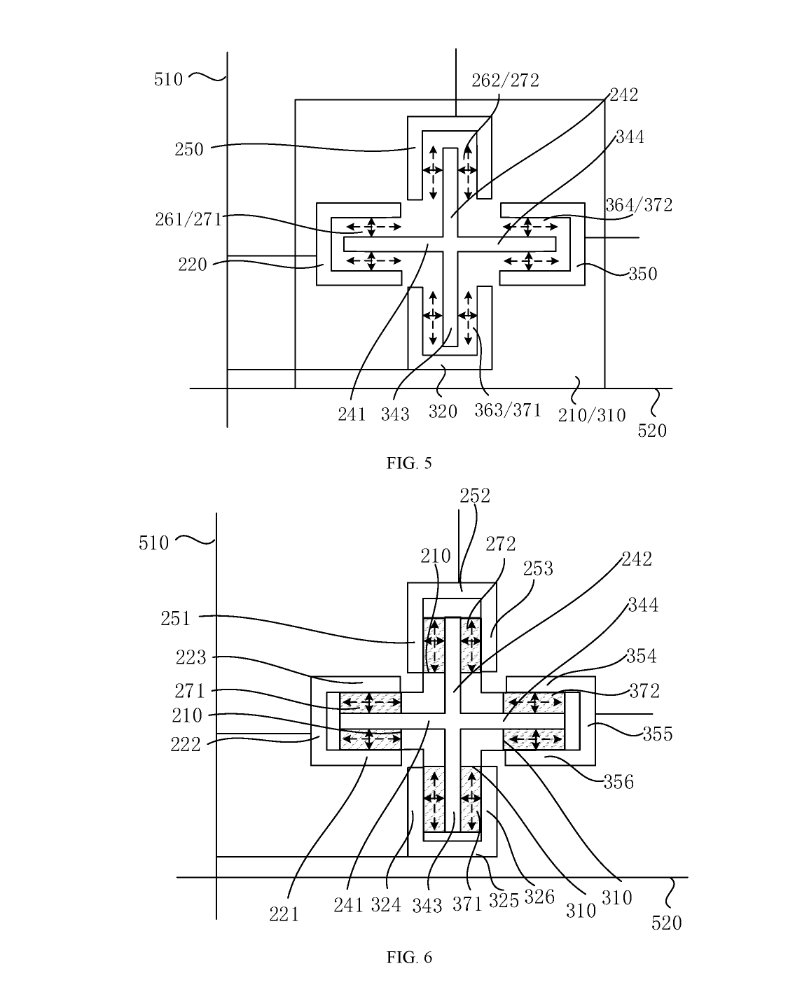

FIG. 4 is a schematic diagram of an array substrateincluding a second active switch according to the first embodiment of the present disclosure, and FIG. 5 is a partially enlarged schematic diagram of the active switch in FIG. 4. As shown in FIGS. 4-5, the dashed arrows in FIG. 5 indicate the width of the channel, and the solid arrows indicate the length of the channel. The present disclosure further provides a second active switch 300, where the second source electrode 320 and the second drain electrode 350 are U-shaped.

Specifically, the array substrate 30 includes the second active switch 300, where the second active switch 300 includes a second gate electrode 310, a second source electrode 320, a second connecting electrode 340, and a second drain electrode 350. The second gate electrode 310, the second source electrode 320, the second connecting electrode 340, and the second drain electrode 350 are disposed on the substrate 100. The pixel electrodes 400 are further connected to the second drain electrode 350.

A third semiconductor structure 363 is disposed between the second source electrode 320 and the second connecting electrode 340. A fourth semiconductor structure 364 is disposed between the second connecting electrode 340 and the second drain electrode 350. The second source electrode 320, the third semiconductor structure 363, the second connecting electrode 340, the fourth semiconductor structure 364, and the second drain electrode 350 are connected in series.

A channel formed between the second source electrode 320 and the second connecting electrode 340 is defined as a second source channel 371. A channel formed between the second drain electrode 350 and the second connecting electrode 340 is defined as a second drain channel 372. The length direction of the second source channel 371 is perpendicular to the length direction of the second drain channel 372.

The second connecting electrode 340 includes a third connecting electrode portion 343 and a fourth connecting electrode portion 344, and the third connecting electrode portion 343 is vertically connected to the fourth connecting electrode portion 344.

The second source electrode 320 includes a fourth source portion 324, a fifth source portion 325, and a sixth source portion 326. The fourth source portion 324, the fifth source portion 325, and the sixth source portion 326 are connected in series. The fourth source portion 324 and the sixth source portion 326 are disposed on two sides of the third connecting electrode portion 343.

The second drain electrode 350 includes a fourth drain portion 354, a fifth drain portion 355, and a sixth drain portion 356. The fourth drain portion 354, the fifth drain portion 355, and the sixth drain portion 356 are connected in series. The fourth drain portion 354 and the sixth drain portion 356 are disposed on two sides of the fourth connecting electrode portion 344.

Exemplarily, the second active switch 300 is a bottom-gate active switch. The second gate electrode 310 is disposed within the first metal layer 610. The second source electrode 320, the second connecting electrode 340, and the second drain electrode 350 are disposed within the second metal layer 630. The third semiconductor structure 363 and the fourth semiconductor structure 364 are disposed between the first insulating layer 620 and the second metal layer 630.

Exemplarily, the second active switch 300 is a top-gate active switch. The second gate electrode 310 is disposed within the first metal layer 610. The second source electrode 320, the second connecting electrode 340, and the second drain electrode 350 are disposed within the first metal layer 610. The third semiconductor structure 363 and the fourth semiconductor structure 364 are disposed between the substrate 100 and the first metal layer 610.

Where the data lines 510 aresimultaneously connected to the first source electrode 220 and the second source electrode 320, and the scan lines 520 are simultaneously connected to the first gate electrode 210 and the second gate electrode 310. By adding the second active switch 300, the first active switch 200 and the second active switch 300 are equivalent to being arranged in parallel to improve the charging capability of the pixel electrode 400. When one of the first active switch 200 and the second active switch 300 is damaged, the other one can continue to work, preventing the failure of the pixel unit region and avoiding the problem of black spots or white spots.

Furthermore, the first gate electrode 210 and the second gate electrode 310 are disposed on the same layer and may be directly integrated into a single piece, and the first source electrode 220, the first connecting electrode 240, the first drain electrode 250, the second source electrode 320, the second connecting electrode 340, and the second drain electrode 350 are disposed on the same layer, which simplifies the manufacturing process and reduces the fabrication difficulty.

The first connecting electrode portion 241 is arranged in parallel with the fourth connecting electrode portion 344. The first connecting electrode portion 241 is perpendicular to the third connecting electrode portion 343. The second connecting electrode portion 242 is arranged in parallel with the third connecting electrode portion 343. The second connecting electrode portion 242 is perpendicular to the fourth connecting electrode portion 344.

Exemplarily, the first gate electrode 210 may be directly connected to the second gate electrode 310, the first connecting electrode 240 may may be directly connected to the second connecting electrode 340, and the first connection electrode 240 and the second connection electrode 340 are in a cross-shape.

Exemplarily, when the display panel 10 is folded along the X-axis 810 direction, the length of the first source channel 271 and the width of the first drain channel 272 increase or decrease synchronously, while the width of the first source channel 271 and the length of the first drain channel 272 remain unchanged; the width of the second source channel 371 and the length of the second drain channel 372 increase or decrease synchronously, while the length of the second source channel 371 and the width of the second drain channel 372 remain unchanged, thereby achieving a better effect of mutual offset.

Exemplarily, when the display panel 10 is folded along the Y-axis 820 direction, the width of the first source channel 271 and the length of the first drain channel 272 increase or decrease synchronously, while the length of the first source channel 271 and the width of the first drain channel 272 remain unchanged; the length of the second source channel 371 and the width of the second drain channel 372 increase or decrease synchronously, while the width of the second source channel 371 and the length of the second drain channel 372 remain unchanged, thereby achieving a better effect of mutual offset.

FIG. 6 is a schematic diagram of the first gate electrode and the second gate electrode according to the first embodiment of the present disclosure. As shown in FIG. 6, since the first source electrode 220, the first drain electrode 250, the second source electrode 320, and the second drain electrode 350 are all U-shaped, the orthographic projection of the first gate electrode 210 on the substrate 100 only covers the projection of the channel formed between the first source portion 221 and the first connecting electrode portion 241 on the substrate 100, the projection of the channel formed between the third source portion 223 and the first connecting electrode portion 241 on the substrate 100, the projection of the channel formed between the first drain portion 251 and the second connecting electrode portion 242 on the substrate 100, and the projection of the channel formed between the third drain portion 253 and the second connecting electrode portion 242 on the substrate 100, thereby avoiding the impact of channel variations between the second source portion 222 and the first connecting electrode portion 241, as well as between the second drain portion 252 and the second connecting electrode portion 242.

The orthographic projection of the second gate electrode 310 on the substrate 100 only covers the projection of the channel formed between the fourth source portion 324 and the third connecting electrode portion 343 on the substrate 100, the projection of the channel formed between the sixth source portion 326 and the third connecting electrode portion 343 on the substrate 100, the projection of the channel formed between the fourth drain portion 354 and the fourth connecting electrode portion 344 on the substrate 100, and the projection of the channel formed between the sixth drain portion 356 and the fourth connecting electrode portion 344 on the substrate 100, thereby avoiding the impact of channel variations between the fifth source portion 325 and the third connecting electrode portion 343, as well as between the fifth drain portion 355 and the fourth connecting electrode portion 344.

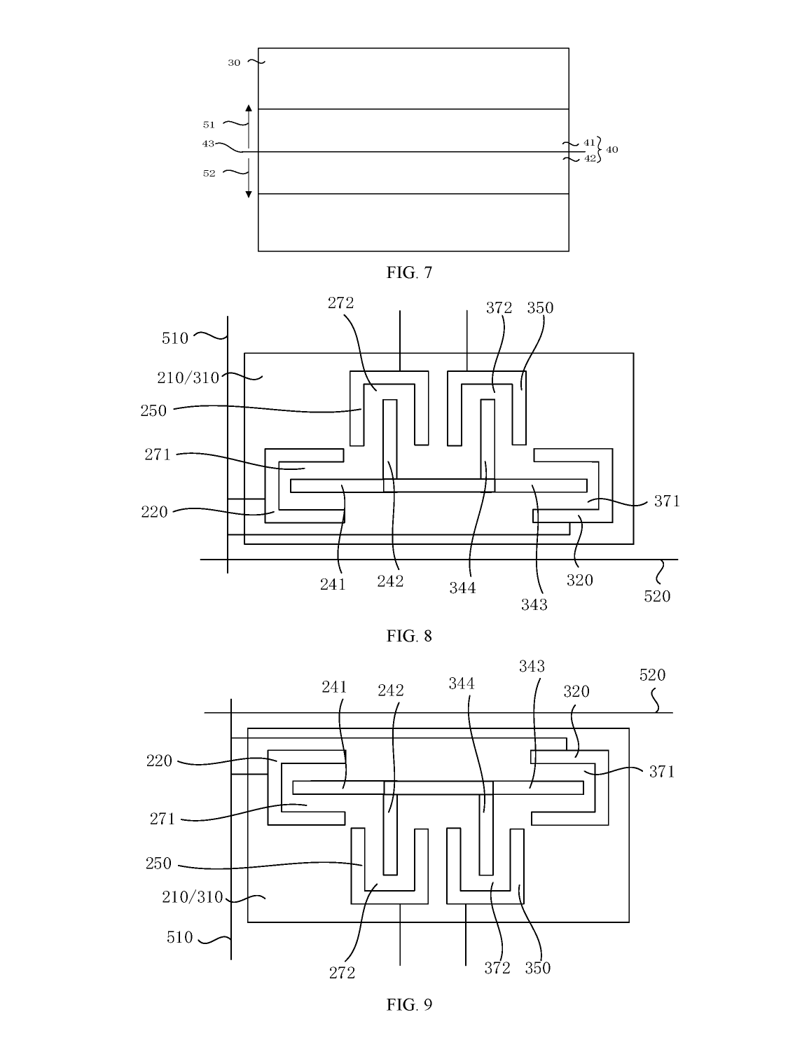

FIG. 7 is a schematic plan diagram of an array substrate in a laterally folded stateaccording to the first embodiment of the present disclosure, FIG. 8 is a schematic diagram of an active switch located at a first folding region according to the first embodiment of the present disclosure, and FIG. 9 is a schematic diagram of an active switch located at a second folding region according to the first embodiment of the present disclosure. As shown in FIGS. 7-9, the array substrate 30 includes a folding region 40, which is located in the middle of the array substrate 30. The middle portion of the folding region 40 is defined as a folding line 43. Within the folding region 40, the directions extending from the width of the folding line 43 to two sides are respectively defined as a first direction 51 and a second direction 52. The extension region of the folding line 43 along the first direction 51 is a first folding region 41, and the extension region of the folding line 43 along the second direction 52 is a second folding region 42. The changes in the length and width of the first source channel 271, the first drain channel 272, the second source channel 371, and the second drain channel 372 would be smaller when farther away from the folding line 43.

Since the length of the first source channel 271 is smaller than the width of the first drain electrode 250, the variation in the length of the first source channel 271 is smaller than the variation in the width of the first drain channel 272 when folding along the length direction of the X-axis 810.

Referring to FIG. 8, when the array substrate 30 is applied in the display panel 10 folded along the length direction of the X-axis 810, within the first folding region 41, the first drain channel 272 is located on the side of the first source channel 271 away from the folding line 43. Referring to FIG. 9, within the second folding region 42, the first drain channel 272 is also located on the side of the first source channel 271 away from the folding line 43.This ensures that whether in the first folding region 41 or the second folding region 42, the variation in the length of the first source channel 271 and the variation in the width of the first drain channel 272 may complement each other more effectivelywhen folding along the length direction of the X-axis 810, avoiding excessive differences.

Correspondingly, within the first folding region 41, the second drain channel 372 is located on the side of the second source channel 371 away from the folding line 43. Within the second folding region 42, the second drain channel 372 is located on the side of the second source channel 371 away from the folding line 43. This ensures that whether in the first folding region 41 or the second folding region 42, the variation in the length of the second source channel 371 and the variation in the width of the second drain channel 372 may complement each other more effectivelywhen folding along the length direction of the X-axis 810, avoiding excessive differences.

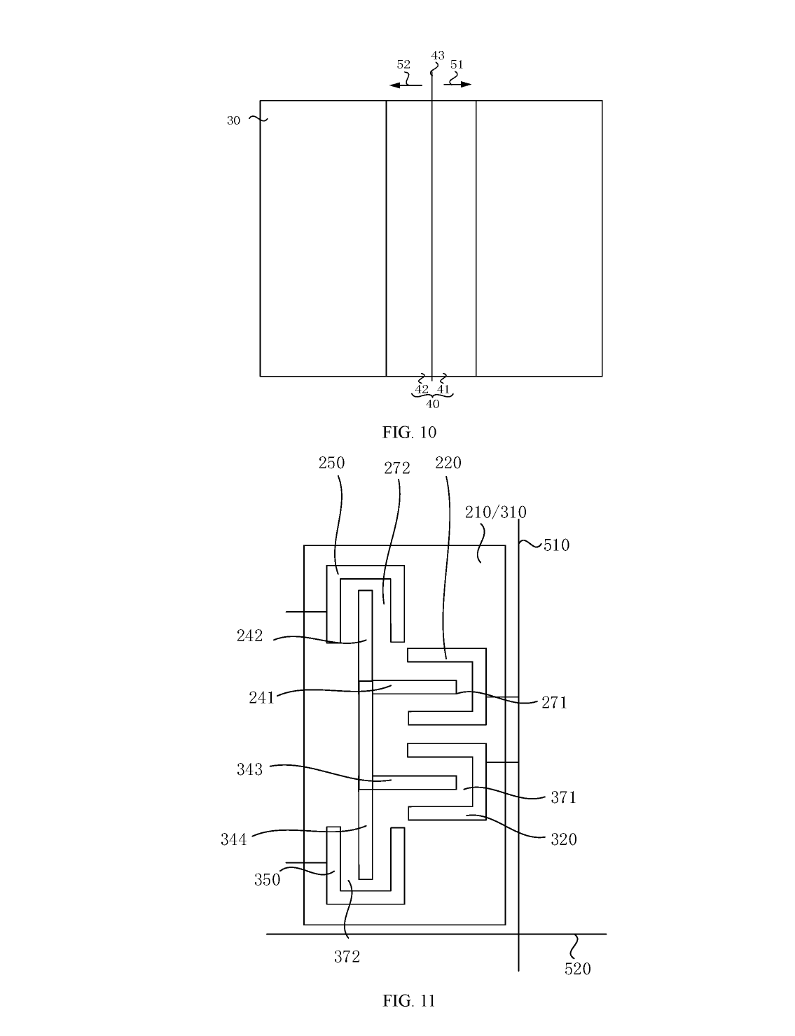

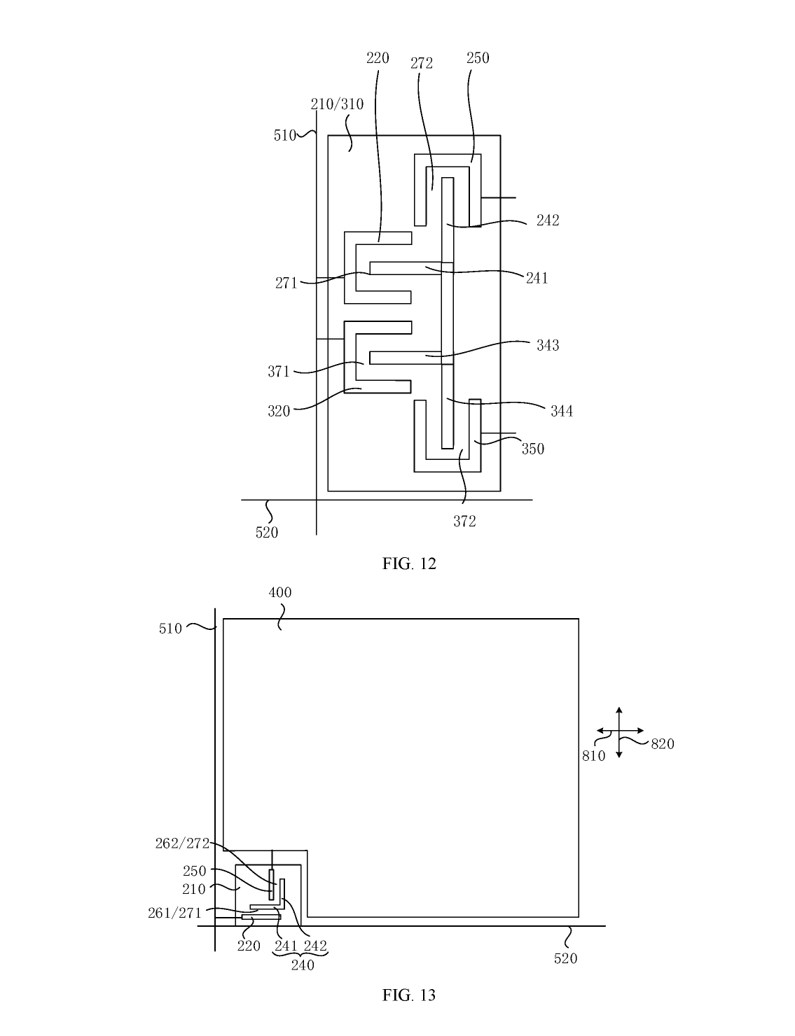

FIG. 10 is a schematic plan diagram of an array substrate in a laterally folded state according to the first embodiment of the present disclosure, FIG. 11 is a schematic diagram of an active switch located at the first folding region according to the first embodiment of the present disclosure, and FIG. 12 is a schematic diagram of an active switch located at the second folding region according to the first embodiment of the present disclosure. As shown in FIGS. 10-12, when the array substrate 30 is applied in a display panel 10 folded along the length direction of the Y-axis 820, referring to FIG. 11, within the first folding region 41, the first drain channel 272 is located on the side of the first source channel 271 close to the folding line 43, and referring to FIG. 12, within the second folding region 42, the first drain channel 272 is located on the side of the first source channel 271 close to the folding line 43.

Within the first folding region 41, the second drain channel 372 is located on the side of the second source channel 371 close to the folding line 43. Within the second folding region 42, the second drain channel 372 is located on the side of the second source channel 371 close to the folding line 43.This ensures that whether in the first folding region 41 or the second folding region 42, when folding along the length direction of the Y-axis 820, the variations in the channels of the first source electrode 220, the channels of the first drain electrode 250, the variation in the second source channel 371, and the variation in the width of the second drain channel 372 may complement each other more effectively.

### Embodiment 2

FIG. 13 is a schematic plan diagram of an array substrate according to the second embodiment of the present disclosure. As shown in FIG. 13, different from the first embodiment, the first source electrode 220 and the first drain electrode 250 disclosed in this embodiment are I-shaped, and the specific configuration is as follows: the first connecting electrode 240 includes the first connecting electrode portion 241 and the second connecting electrode portion 242, and the first connecting electrode portion 241 is vertically connected to the second connecting electrode portion 242.

The first semiconductor structure 261 is connected to the first source electrode 220 and the first connecting electrode portion 241, and the second semiconductor structure 262 is connected to the first drain electrode 250 and the second connecting electrode portion 242.

The first source electrode 220 isarranged in parallel with the first connecting electrode portion 241, and the first drain electrode 250 is arranged in parallel with the second connecting electrode portion 242.

In other words, the first source electrode 220 and the second source electrode 320 are I-shaped. Compared with the solution of the first embodiment, the occupied area of the first active switch 200 can be reduced, thereby providing a larger area for the common electrode 710 to increase the size of the storage capacitor.

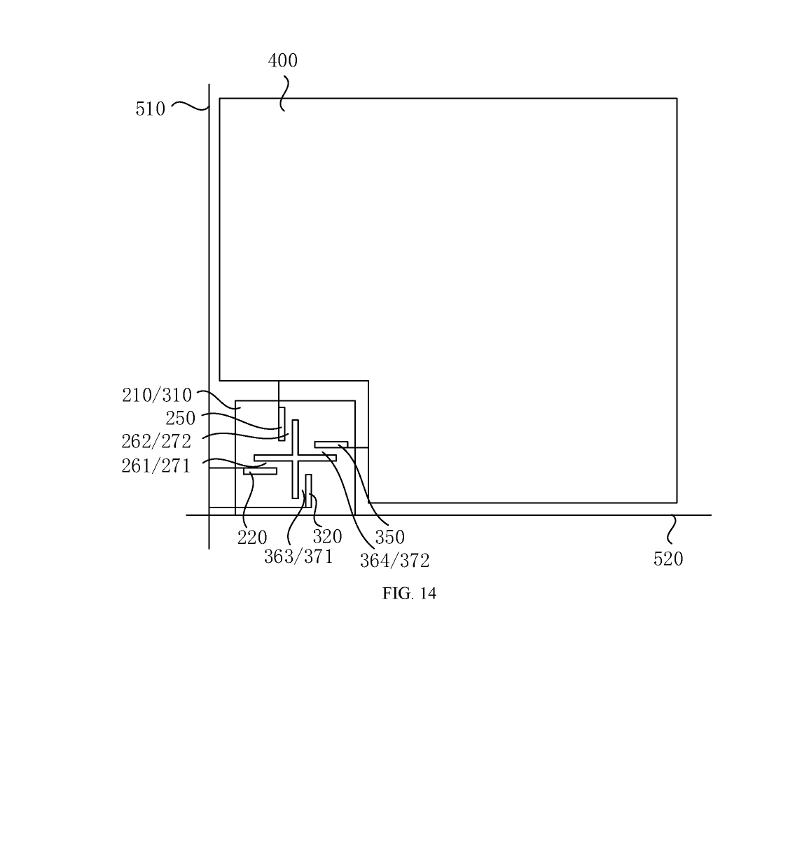

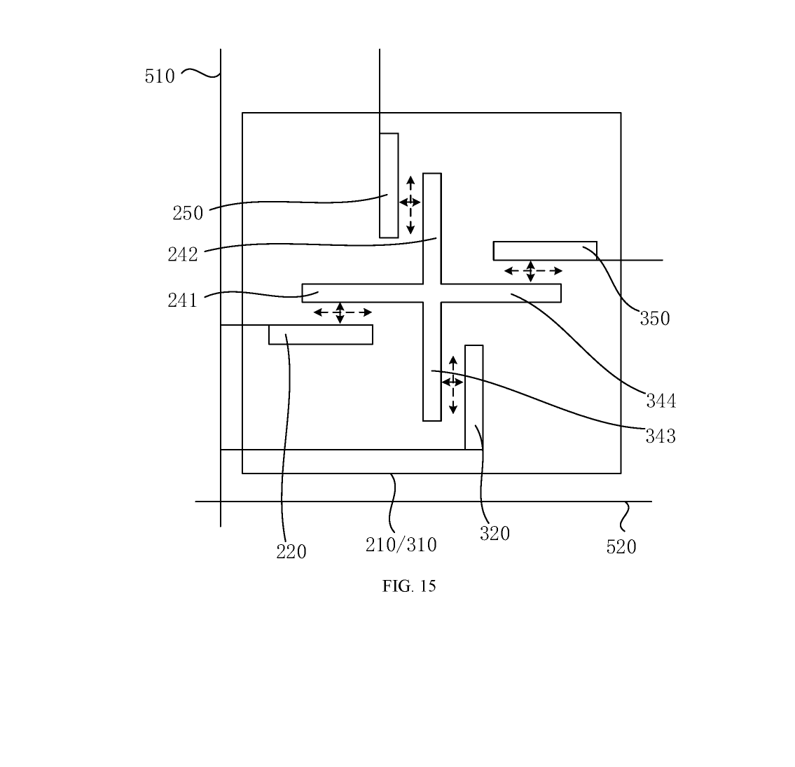

FIG. 14 is a schematicplan diagram of an array substrate including dual active switches according to the second embodiment of the present disclosure., and FIG. 15 is a partially enlarged schematic diagram of the active switch in FIG. 14. In FIG. 15, the dashed arrows indicate the width of the channel, and the solid arrows indicate the length of the channel. As shown in FIGS. 14-15, the second active switch 300 may also be provided in the second embodiment. The array substrate 30 includes the second active switch 300 including the second gate electrode 310, the second source electrode 320, the second connecting electrode 340, and the second drain electrode 350. The second gate electrode 310, the second source electrode 320, the second connecting electrode 340, and the second drain electrode 350 are disposed on the substrate 100. The pixel electrodes 400 are connected to the second drain electrode 350.

The third semiconductor structure 363 is disposed between the second source electrode 320 and the second connecting electrode 340. The fourth semiconductor structure 364 is disposed between the second connecting electrode 340 and the second drain electrode 350. The second source electrode 320, the third semiconductor structure 363, the second connecting electrode 340, the fourth semiconductor structure 364, and the second drain electrode 350 are connected in series.

The channel formed between the second source electrode 320 and the second connecting electrode 340 is defined as the second source channel 371, and the channel between the second drain electrode 350 and the second connecting electrode 340 is defined as the second drain channel 372. The length direction of the second source channel 371 is perpendicular to the length direction of the second drain channel 372.

The second connecting electrode 340 includes the third connecting electrode portion 343 and the fourth connecting electrode portion 344, and the third connecting electrode portion 343 is vertically connected to the fourth connecting electrode portion 344.

The third semiconductor structure 363 is connected to the second source electrode 320 and the third connecting electrode portion 343. The fourth semiconductor structure 364 is connected to the second drain electrode 350 and the fourth connecting electrode portion 344. The second source electrode 320 is arranged in parallel with the third connecting electrode portion 343. The second drain electrode 350 is arranged in parallel with the fourth connecting electrode portion 344.

Where the data lines 510 aresimultaneouslyconnected to the first source electrode 220 and the second source electrode 320. The scan line 520 are simultaneously connected to the first gate electrode 210 and the second gate electrode 310. By adding the second active switch 300, the first active switch 200 and the second active switch 300 are equivalent to being arranged in parallel to improve the charging capability of the pixel electrode 400. When one of the first active switch 200 and the second active switch 300 is damaged, the other one can continue to work, preventing the failure of the pixel unit region and avoiding the problem of black spots or white spots.

The first gate electrode 210 and the second gate electrode 310 are disposed on the same layer. The first source electrode 220, the first connecting electrode 240, the first drain electrode 250, the second source electrode 320, the second connecting electrode 340, and the second drain electrode 350 are disposed on the same layer.

The first connecting electrode portion 241 is arranged in parallel with the fourth connecting electrode portion 344. The first connecting electrode portion 241 is perpendicular to the third connecting electrode portion 343. The second connecting electrode portion 242 is arranged in parallel with the third connecting electrode portion 343. The second connecting electrode portion 242 is perpendicular to the fourth connecting electrode portion 344.

The first source electrode 220 and the first drain electrode 250 are respectively disposed on the two sides of the first connecting electrode portion 241, and the second source electrode 320 and the second drain electrode 350 are respectively disposed on the two sides of the fourth connecting electrode portion 344. Alternatively, the first source electrode 220 and the first drain electrode 250 are respectively disposed on the two sides of the second connecting electrode portion 242, and the second source electrode 320 and the second drain electrode 350 are respectively disposed on the two sides of the third connecting electrode portion 343.This can prevent any two of the first source electrode 220, the first drain electrode 250, the second source electrode 320, and the second drain electrode 350 from being too close to each other, thereby simplifying the manufacturing difficulty and improving the production yield, and further avoiding the risk of breakdown between any two of the first source electrode 220, the first drain electrode 250, the second source electrode 320, and the second drain electrode 350.

It should be noted that the inventive concept of the present disclosure may be formed into many embodiments, but limitations of the application document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions.For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. An array substrate,wherein thearray substratecomprises a substrate, a first active switch, and pixel electrodes; wherein the first active switch comprises a first gate electrode, a first source electrode, a first connecting electrode, and a first drain electrode; the first gate electrode, the first source electrode, the first connecting electrode, the first drain electrode, and the pixel electrodes are disposed on the substrate;
wherein a first semiconductor structure is disposed between the first source electrode and the first connecting electrode, and a second semiconductor structure is disposed between the first connecting electrode and the first drain electrode; the first source electrode, the first semiconductor structure, the first connecting electrode, the second semiconductor structure, and the first drain electrode are connected in series; the pixel electrodes are connected to the first drain electrode;
wherein a channel formed between the first source electrode and the first connecting electrode is defined as a first source channel, a channel formed between the first drain electrode and the first connecting electrode is defined as a first drain channel, and the length direction of the first source channel and the length direction of the first drain channel form an angle.

2. The array substrate according to claim 1, wherein the length direction of the first source channel is perpendicular to the length direction of the first drain channel.

3. The array substrate according to claim 2, wherein the first connecting electrodecomprisesa first connecting electrode portion and a second connecting electrode portion; the first connecting electrode portion is verticallyconnected to the second connecting electrode portion;
wherein the first semiconductor structure is connected to the first source electrode and the first connecting electrode portion; the second semiconductor structure is connected to the first drain electrode and the second connecting electrode portion;
wherein the first source electrode is arranged in parallel with the first connecting electrode portion; the first drain electrode is arranged in parallel with the second connecting electrode portion.

4. The array substrate according to claim 3,wherein the array substrate comprises a second active switch comprising a second gate electrode, a second source electrode, a second connecting electrode, and a second drain electrode; the second gate electrode, the second source electrode, the second connecting electrode, and the second drain electrode are disposed on the substrate; the pixel electrodes are connected to the second drain electrode;
wherein a third semiconductor structure is disposed between the second source electrode and the second connecting electrode; a fourth semiconductor structure is disposed between the second connecting electrode and the second drain electrode; the second source electrode, the third semiconductor structure, the second connecting electrode, the fourth semiconductor structure, and the second drain electrode are connected in series;
wherein a channel formed between the second source electrode and the second connecting electrode is defined as a second source channel, a channel formed between the second drain electrode and the second connecting electrode is defined as a second drain channel, and the length direction of the second source channel is perpendicular to the length direction of the second drain channel;
wherein the second connecting electrode comprises a third connecting electrode portion and a fourth connecting electrode portion, and the third connecting electrode portion is vertically connected to the fourth connecting electrode portion;
wherein the third semiconductor structure is connected to the second source electrode and the third connecting electrode portion, and the fourth semiconductor structure is connected to the second drain electrode and the fourth connecting electrode portion;
wherein the second source electrode is arranged in parallel with the third connecting electrode portion; the second drain electrode is arranged in parallel with the fourth connecting electrode portion.

5. The array substrate according to claim 4,wherein the first gate electrode and the second gate electrode are disposed on the same layer; the first source electrode, the first connecting electrode, the first drain electrode, the second source electrode, the second connecting electrode, and the second drain electrode are disposed on the same layer;
wherein the first connecting electrode portion is arranged in parallel with the fourth connecting electrode portion, the first connecting electrode portion is perpendicular to the third connecting electrode portion, the second connecting electrode portion is arranged in parallel with the third connecting electrode portion, and the second connecting electrode portion is perpendicular to the fourth connecting electrode portion;
wherein the first source electrode and the first drain electrode are respectively disposed on two sides of the first connecting electrode portion, and the second source electrode and the second drain electrode are respectively disposed on two sides of the fourth connecting electrode portion; or the first source electrode and the first drain electrode are respectively disposed on two sides of the second connecting electrode portion, and the second source electrode and the second drain electrode are respectively disposed on two sides of the third connecting electrode portion.

6. The array substrate according to claim 2, wherein the first connecting electrode comprises the first connecting electrode portion and the second connecting electrode portion, and the first connecting electrode portion is vertically connected to the second connecting electrode portion;
wherein the first source electrode comprises a first source portion, a second source portion, and a third source portion; the first source portion, the second source portion, and the third source portion are connected in series; the first source portion and the third source portion are disposed on the two sides of the first connecting electrode portion;
wherein the first drain electrode comprises a first drain portion, a second drain portion, and a third drain portion; the first drain portion, the second drain portion, and the third drain portion are connected in series; the first drain portion and the third drain portion are disposed on the two sides of the second connecting electrode portion.

7. The array substrate according to claim 6, wherein the array substrate comprises the second active switch comprising the second gate electrode, the second source electrode, the second connecting electrode, and the second drain electrode; the second gate electrode, the second source electrode, the second connecting electrode, and the second drain electrode are disposed on the substrate; the pixel electrodes are connected to the second drain electrode;
wherein the third semiconductor structure is disposed between the second source electrode and the second connecting electrode; the fourth semiconductor structure is disposed between the second connecting electrode and the second drain electrode; the second source electrode, the third semiconductor structure, the second connecting electrode, the fourth semiconductor structure, and the second drain electrode are connected in series;
wherein the channel formed between the second source electrode and the second connecting electrode is defined as the second source channel; the channel formed between the second drain electrode and the second connecting electrode is defined as the second drain channel; the length direction of the second source channel is perpendicular to the length direction of the second drain channel;
wherein the second connecting electrode comprises a third connecting electrode portion and a fourth connecting electrode portion; the third connecting electrode portion is vertically connected to the fourth connecting electrode portion;
wherein the second source electrode comprises a fourth source portion, a fifth source portion, and a sixth source portion; the fourth source portion, the fifth source portion, and the sixth source portion are connected in series; the fourth source portion and the sixth source portion are disposed on the two sides of the third connecting electrode portion;
wherein the second drain electrode comprises a fourth drain portion, a fifth drain portion, and a sixth drain portion; the fourth drain portion, the fifth drain portion, and the sixth drain portion are connected in series; the fourth drain portion and the sixth drain portion are disposed on the two sides of the fourth connecting electrode portion.

8. The array substrate according to claim 7, wherein the first gate electrode and the second gate electrode are disposed on the same layer; the first source electrode, the first connecting electrode, the first drain electrode, the second source electrode, the second connecting electrode, and the second drain electrode are disposed on the same layer;
wherein the first connecting electrode portion is arranged in parallel with the fourth connecting electrode portion; the first connecting electrode portion is perpendicular to the third connecting electrode portion; the second connecting electrode portion is arranged in parallel with the third connecting electrode portion; the second connecting electrode portion is perpendicular to the fourth connecting electrode portion.

9. The array substrate according to claim 1, wherein the array substrate further comprises data lines and scan lines; the data lines and the scan lines are disposed on the substrate; the data lines are connected to the first source electrode of the first active switch; the scan linesare connected to the first gate electrode of the first active switch.

10. The array substrate according to claim 3, wherein the first source electrode and the first drain electrode are I-shaped.

11. The array substrate according to claim 6, wherein the first source electrode and the first drain electrode are U-shaped.

12. The array substrate according to claim 1, wherein the first active switch is a bottom-gate active switch; the first gate electrode is disposedwithin a first metal layer; the first source electrode, the first connecting electrode, and the first drain electrode are disposedwithina second metal layer; the first semiconductor structure and the second semiconductor structure are disposed between a first insulating layer and the second metal layer.

13. The array substrate according to claim 1, wherein the first active switch is a top-gate active switch; the first gate electrode is disposedwithin the second metal layer; the first source electrode, the first connecting electrode, and the first drain electrode are disposedwithin the first metal layer; the first semiconductor structure and the second semiconductor structure are disposed between the substrate and the first metal layer.

14. The array substrate according to claim 4, wherein the second active switch is a bottom-gate active switch; the second gate electrode is disposedwithin the first metal layer; the second source electrode, the second connecting electrode, and the second drain electrode are disposedwithin the second metal layer; the third semiconductor structure and the fourth semiconductor structure are disposed between the first insulating layer and the second metal layer.

15. The array substrate according to claim 4, wherein the second active switch is a top-gate active switch; the second gate electrode is disposedwithin the first metal layer; the second source electrode, the second connecting electrode, and the second drain electrode are disposedwithin the first metal layer; the third semiconductor structure and the fourth semiconductor structure are disposed between the substrate and the first metal layer.

16. The array substrate according to claim 4, wherein the array substrate further comprisesthe data lines and the scan lines; the data lines and the scan lines are disposed on the substrate; the data lines are connected to the first source electrode and the second source electrode; the scan lines are connected to the first gate electrode and the second gate electrode.

17. Thearray substrate according to claim 1, wherein the array substrate further comprises a common electrode; the common electrode is disposed within the first metal layer or the second metal layer; a storage capacitor is formed between the common electrode and the pixel electrodes.

18. A display panel, wherein the the display panel comprises a driving circuit and the array substrate; the array substrate comprises the substrate, the first active switch, and the pixel electrodes; the first active switch comprises the first gate electrode, the first source electrode, the first connecting electrode, and the first drain electrode; the first gate electrode, the first source electrode, the first connecting electrode, the first drain electrode, and the pixel electrodes are disposed on the substrate; the first semiconductor structure is disposed between the first source electrode and the first connecting electrode; the second semiconductor structure is disposed between the first connecting electrode and the first drain electrode; the first source electrode, the first semiconductor structure, the first connecting electrode, the second semiconductor structure, and the first drain electrode are connected in series; the pixel electrodes are connected to the first drain electrode;
wherein the channel formed between the first source electrode and the first connecting electrode is defined as the first source channel; the channel formed between the first drain electrode and the first connecting electrode is defined as the first drain channel; the length direction of the first source channel and the length direction of the first drain channel form the angle;
wherein the driving circuit is connected to the array substrate to drive the array substrate.

19. The display panel according to claim 18, wherein the display panel further comprises a reflective film layer and a common electrode layer; the reflective film layer is disposed between the array substrate and the common electrode layer.

20. The display panel according to claim 19, wherein the reflective film layer compromises microcapsules, and the microcapsules are filled with electrophoretic particles.
